(19) United States
(12) Patent Application Publication
(10) Pub. No.: US 2010/0171395 A1
(43) Pub. Date: Jul. 8, 2010

(54) CURVED ULTRASONIC ARRAY TRANSDUCERS

(75) Inventors: Jonathan M. Cannata, Santa Monica, CA (US); Jay A. Williams, Torrance, CA (US); K. Kirk Shung, Monterey Park, CA (US)

Correspondence Address: MCDERMOTT WILL & EMERY LLP, 2049 CENTURY PARK EAST, 38th Floor, LOS ANGELES, CA, 90067-3208, US

(73) Assignee: UNIVERSITY OF SOUTHERN CALIFORNIA, Los Angeles, CA (US)

(21) Appl. No.: 12/605,082

(22) Filed: Oct. 23, 2009

Related U.S. Application Data
(60) Provisional application No. 61/108,117, filed on Oct. 24, 2008.

(51) Int. Cl. H01L 41/047; H01L 41/053; H05K 1/00; H01L 41/22

(52) U.S. Cl. 310/366; 174/250; 174/254; 29/25.35

(57) ABSTRACT

An ultrasonic array transducer having an array of piezoelectric elements may be made with a curvature which may enable the piezoelectric elements to control the way in which ultrasonic energy is focused by the transducer. A substrate that has a set of element electrodes on a surface of the substrate may be created. Each element electrode may be electrically isolated from the others and configured to correspond to the location of one of the piezoelectric elements. A piezoelectric component which includes piezoelectric material may be bonded to the substrate such that each element electrode is juxtaposed next to the piezoelectric component. The surface of the substrate and/or to the piezoelectric material may have the curvature while they are separated and prior to the bonding. The bonding may be performed in a manner that results in the array of piezoelectric elements having the curvature.

### CROSS-REFERENCE TO RELATED APPLICATION

This application is based upon and claims priority to U.S. Provisional Patent Application No. 61/108,117, entitled “Method for Manufacture of an Arrayed Ultrasonic Transducer,” filed Oct. 24, 2008, attorney docket number 028080-0415. The entire content of this application is incorporated herein by reference.

### STATEMENT REGARDING FEDERALLY SPONSORED RESEARCH

This invention was made with government support under Contract No. P41EB002182 awarded by the National Institutes of Health. The government has certain rights in the invention.

### BACKGROUND

1. Technical Field

This disclosure relates to ultrasonic array transducers and methods of manufacturing them.

2. Description of Related Art

Ultrasonic array transducers are used for a broad variety of applications. For example, they are used in imaging applications for medical diagnostics.

Ultrasonic array transducers may contain a set of piezoelectric elements. Particularly for high frequency devices, the width of the piezoelectric elements may be so narrow as to make it very difficult to solder or wire-bond a lead to each one. A circuit interconnect having a set of element electrodes may instead be deposited or patterned on or bonded to the piezoelectric elements to facilitate the needed electrical connections.

Ultrasonic array transducers may use a lens to obtain a fixed off-axis (elevation) focus. However, these lenses may attenuate the signal, particularly at high frequencies.

“Self-focused” arrays may be made which focus the energy off-axis (elevation) without a lens. One way to accomplish this is to impart a curvature to the bonded combination of the piezoelectric elements and the circuit interconnect. However, imparting this curvature may compromise needed electrical connections between the piezoelectric elements and the circuit interconnect.

### SUMMARY

An ultrasonic array transducer having an array of piezoelectric elements may be made with a curvature which may enable the piezoelectric elements to control the way in which ultrasonic energy is focused by the transducer.

A substrate that has a set of element electrodes on a surface of the substrate may be created. Each element electrode may be electrically isolated from the others and configured to correspond to the location of one of the piezoelectric elements. A piezoelectric component which includes piezoelectric material may be bonded to the surface of the substrate such that each element electrode is juxtaposed next to the piezoelectric component. The surface of the substrate and/or to the piezoelectric material may have the curvature while they are separated and prior to the bonding. The bonding may be performed in a manner that results in the array of piezoelectric elements having the curvature.

The piezoelectric component may include a set of element electrodes on one side of the piezoelectric material. Each may be electrically isolated from the others and configured to correspond to the location of one of the piezoelectric elements. The element electrodes on the substrate may be oriented with respect to the element electrodes on the piezoelectric material such that the element electrodes on the substrate come in electrical contact with the element electrodes on the piezoelectric material when assembled and/or bonded.

The electrodes on the substrate may rest against a side of the piezoelectric material after bonding. There may be no other element electrodes between first set of element electrodes and the piezoelectric material either before, during, or after bonding.

The curvature may be created in a surface of backing material.

The element electrodes may be bonded to the curvature in the surface of the backing material.

The element electrodes on the substrate may be part of a substantially flat, flexible circuit inter-connect which includes a flexible support member. The flexible circuit inter-connect may be bonded to the curvature in the surface of the backing.

The curvature may or may not be imparted to the flexible circuit inter-connect in a permanent fashion before it is bonded to the curvature in the surface of the backing.

The piezoelectric material may or may not have the curvature while separated from and before being bonded to the surface of the substrate.

Only a portion of the piezoelectric material may have the curvature while separated from and before being bonded to the substrate. The curved portion of the piezoelectric material may be polarized, while the un-curved portion may not be polarized.

At least one common electrode may be created on an opposite side of the piezoelectric material.

The curvature may be in only a single plane or in multiple planes.

These, as well as other components, steps, features, objects, benefits, and advantages, will now become clear from a review of the following detailed description of illustrative embodiments, the accompanying drawings, and the claims.

### BRIEF DESCRIPTION OF DRAWINGS

The drawings disclose illustrative embodiments. They do not set forth all embodiments. Other embodiments may be used in addition or instead. Details that may be apparent or unnecessary may be omitted to save space or for more effective illustration. Conversely, some embodiments may be practiced without all of the details that are disclosed. When the same numeral appears in different drawings, it refers to the same or like components or steps.

The figures illustrate a process of manufacturing a curved ultrasonic array transducer. The “a” figures illustrate a cross section of materials used in the process through an off-image axis (elevation), while the “b” figures illustrate a cross-section of these materials through an on-image axis (azimuth).

FIGS. 1a and b illustrate a flexible circuit interconnect being bonded to a curved surface of backing material to form a substrate.

FIGS. 2a and b illustrate a piezoelectric component being bonded to the substrate made from the process illustrated in FIGS. 1a and b to form an assembly.

FIGS. 3a and b illustrate a matching layer being bonded to the assembly made from the process illustrated in FIGS. 1a and b and 2a and b.

FIGS. 4a and 4b illustrate an assembled curved ultrasonic array transducer made from the process illustrated in FIGS. 1a, 1b, 2a, 2b, 3a, and 3b.

### DETAILED DESCRIPTION OF ILLUSTRATIVE EMBODIMENTS

Illustrative embodiments are now discussed. Other embodiments may be used in addition or instead. Details that may be apparent or unnecessary may be omitted to save space or for a more effective presentation. Conversely, some embodiments may be practiced without all of the details that are disclosed.

An ultrasonic array transducer may have an array of piezoelectric elements in the azimuth direction. These elements may have a curvature that enables the piezoelectric elements to control the way in which ultrasonic energy is focused by the transducer. There may be one or more separate elements along the elevation direction. There may also be elements or portions of elements in either the azimuth and/or elevation direction that are electrically interconnected.

The curvature may be of any shape or size. The figures illustrate a configuration in which the curvature is in only a single plane, along the length of each piezoelectric element. The curvature may instead be along the consolidated widths of the piezoelectric elements. The curvature may instead be in multiple planes, such as along both the length and the consolidated widths of the piezoelectric elements.

The curvature may be across all or only a portion of the piezoelectric elements. When across only a portion, the portion of the piezoelectric material which is curved may be polarized, while the portion which is not curved may not be polarized. A different polarization configuration may instead be used.

The figures illustrate a process of manufacturing a curved ultrasonic array transducer. The “a” figures illustrate a cross section of materials used in the process through an off-image axis (elevation), while the “b” figures illustrate a cross-section of these materials through an on-image axis (azimuth).

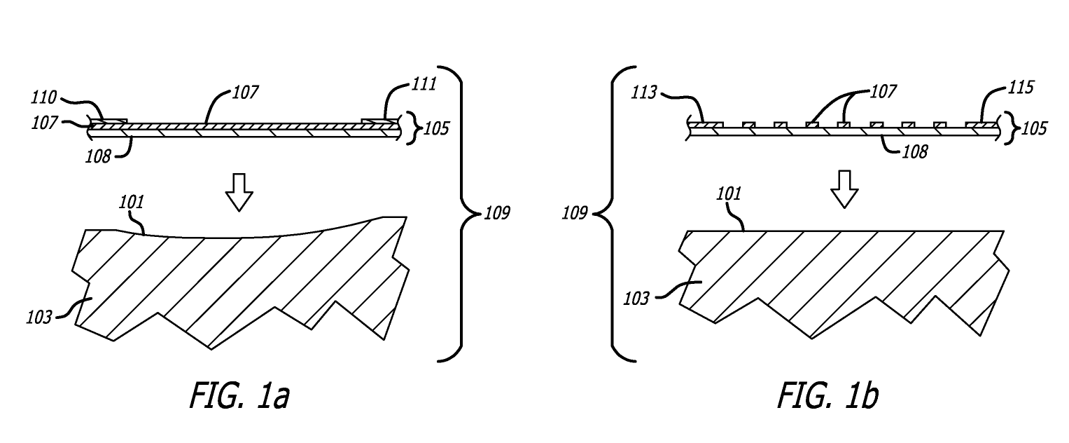

FIGS. 1a and b illustrate a flexible circuit interconnect being bonded to a curved surface of backing material to form a substrate.

As illustrated in FIGS. 1a and b, the desired curvature may be created in a surface 101 of backing material 103. The backing material 103 may be made of any material, such as polymers (e.g., epoxy, plastic, rubber, urethane), metals (e.g., copper, aluminum, tungsten), solids (e.g., glass, quartz, natural stone), or composites (e.g., mixture of materials such as epoxy and tungsten powder). The curvature may be created through any process, such as through machining, molding, or forming the backing material 103 with the desired shape. As illustrated in FIG. 1a, the curvature may be in only a portion of the surface 101. In another configuration, the curvature may be across the entire surface 101.

A flexible circuit interconnect 105 may be created. The flexible circuit interconnect 105 may include a set of element electrodes 107 bonded to a flexible support member 108. Each of the element electrodes 107 may be electrically isolated from the others and configured to correspond to the location of one of the piezoelectric elements within the ultrasonic array transducer.

One or more common electrodes may be formed on the flexible support member 108, such as common electrodes 113 and 115.

Each electrode may be made of electrically-conductive material. Each may be created by depositing electrically-conductive material on the flexible support member 108 using any technique, such as by sputtering and/or evaporation. Various techniques may be used to create the desired pattern, such as photolithography etching, mechanical or laser removal, and/or shadow masking during the deposition. The electrodes may instead be made separately and attached to the flexible support member 108.

The flexible support member 108 may be made of any material. For example, it may be made of a non-conducting dielectric, such as a polyimide. One or more flexible non-conducting overlays may be provided on top of the element electrodes 107, such as non-conducting overlays 110 and/or 111. These overlays may be configured to prevent an electrical short that might otherwise take place during the assembling process that is described below. Other techniques could in addition or instead be used to avoid these shorts, such as a different configuration in some of the components.

The flexible circuit interconnect 105 may or may not also have the desired curvature while it is separated from and before it is bonded to the backing material 103. If it does not have the curvature, the flexible circuit interconnect 105 may be made of materials and configured to have a sufficient degree of flexibility so as to take on the curvature of the surface 101 when being bonded to this surface, as is discussed below. When the flexible circuit interconnect 105 also has the curvature, on the other hand, it may be made of materials that have a memory so as to retain the curvature that is imparted to it. Any technique may be used to impart the curvature to the flexible circuit interconnect 105, such as pressing it between two complementary curved members with or without elevated temperature, or shaping it over a curved support and casting adhesive to fix it in place.

The flexible circuit interconnect 105 may be bonded to the surface 101 of the backing material 103, thereby forming the substrate 109. Any technique may be used to accomplish this bonding. For example, an adhesive may be used. The adhesive may be electrically conductive or electrically non-conductive.

The word “bonded” as used throughout this application (including its use in words such as “bonding”) also has a broader significance and embraces any means by which one component is caused to be attached to another component. In addition to gluing one component to another, for example, the word “bonded” embraces attaching one component to another through a heat process, coating one component upon another, and evaporating material in one component while on another component to cause the one component to adhere to the other component. “Bonding” also includes the use of external force applicators, such as screws and/or clamps.

In another configuration, the element electrodes 107 may be bonded directly to the surface 101 of the backing material 103, without any intervening flexible support member 108. In this configuration, the element electrodes 107 may be formed before they are bonded to the surface 101 or they may be formed during or after the attachment process. When formed during or after the attachment process, any of the techniques that have been discussed above in connection with the formation of the element electrodes 107 on the flexible support member 108 may be used, as well as any other technique.

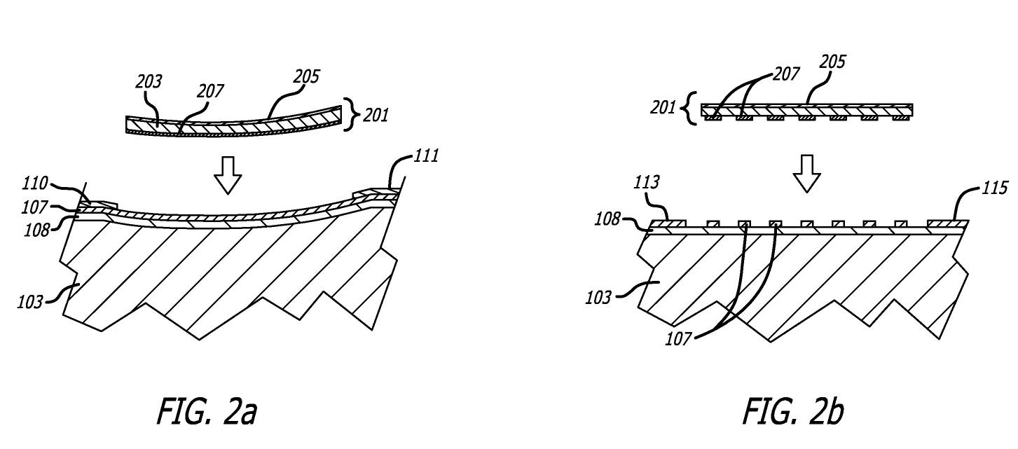

FIGS. 2a and b illustrate a piezoelectric component being bonded to the substrate made from the process illustrated in FIGS. 1(a) and (b) to form an assembly.

As illustrated in FIG. 2, a piezoelectric component 201 may be created by sandwiching piezoelectric material 203 between a common electrode 205 and a set of element electrodes 207.

The piezoelectric material 203 may be any type of material that converts electrical energy into acoustical energy and/or vice versa. The common electrode 205 may be a single electrode across the entire surface of the piezoelectric material 203 or across only a portion of the surface. The common electrode 205 may instead be a set of electrodes, again across either the entire surface of the piezoelectric material 203 or only a portion of the surface.

The element electrodes 207 may each be electrically isolated from the others and configured to correspond to the location of one of the piezoelectric elements. The common electrode 205 and the element electrodes 207 may be created by any means, such as by any of the means discussed above in connection with the element electrodes 107.

Any number of element electrodes 107 and corresponding element electrodes 207 may be used. The number may be dictated by design considerations such as a desired number of image scan-lines, image size, and/or spatial resolution. A number in the range of 30-500 may be used.

As illustrated in FIG. 2, the piezoelectric component 201 may be bonded to the substrate 109. Any bonding technique may be used. For example, an adhesive may be used, such as an electrically non-conductive adhesive. Care may be exercised to ensure that the adhesive does not compromise the connection between element electrodes 107 and element electrodes 207.

Before bonding, the element electrodes 107 may be oriented with respect to the element electrodes 207 so that the element electrodes 107 come in electrical contact with the element electrodes 207 when bonded.

The piezoelectric component 201 may or may not have the curvature while separated from and before being bonded to the substrate 109. If it does not have the curvature, the piezoelectric component 201 may be made of materials and in such a fashion as to be flexible so as to readily take on the curvature in the surface of the substrate 109. If instead the piezoelectric component 201 has the curvature while separated and before being bonded to the substrate 109, the piezoelectric component 201 may be made of material that has a memory so as to retain the curvature which is imposed upon it.

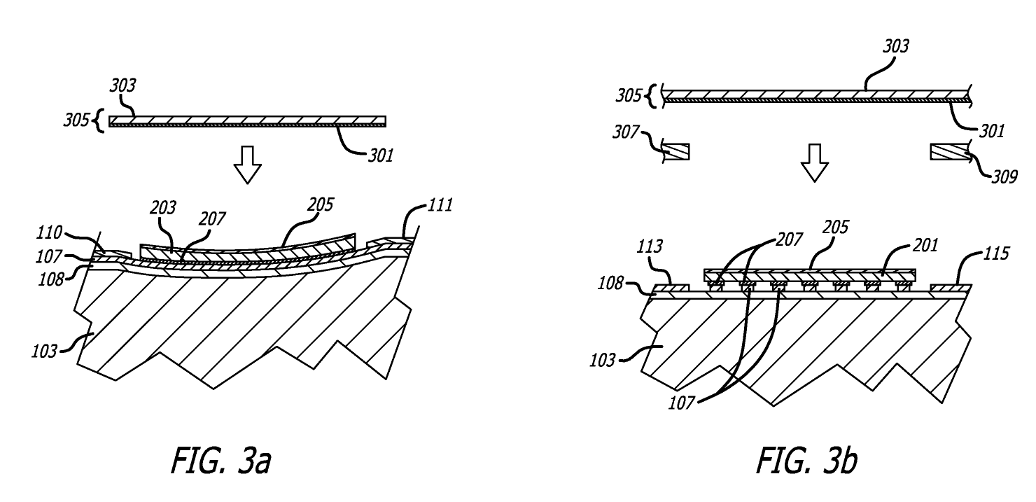

FIGS. 3a and b illustrate a matching layer section being bonded to the assembly made from the process illustrated in FIGS. 1a and b and 2a and b.

As illustrated in FIG. 3, a common electrode 301 may have a matching layer 303. In other embodiments, the matching layer 303 may be omitted.

The common electrode 301 may be configured so as to make an electrical connection between the common electrode 205 on the piezoelectric component 201 and the corresponding common electrode 113 and/or 115 on the substrate 109. To facilitate this electrical contact, electrically conductive material 307 and/or 309 may be used. In other embodiments, components may be configured so as to eliminate the need for the electrically conductive materials 307 and 309, but to instead result in the common electrode 301 making the necessary electrical connection directly. In still further embodiments, a common electrode 301 may not be used at all. For example, an electroplating process, such as sputtering or evaporation may be used instead. Electrical connection to the common electrode 205 may instead be made through other means. The common electrode 205 may instead be deposited on the piezoelectric material 203 and the substrate at the same time, after bonding the piezoelectric material to the substrate.

The common electrode 301 and the matching layer 303 may collectively form a matching layer 305. The thickness and acoustic impedance of the matching layer 305 may be configured to maximize the performance of the device.

The matching layer 305 may or may not be configured with the curvature. If not configured with the curvature, the matching layer 305 may be configured to be flexible so as to take on this curvature when being bonded to the flexible circuit interconnect 105 and piezoelectric component 201. If configured with the curvature, the matching layer 305 may include memory material so as to retain this curvature.

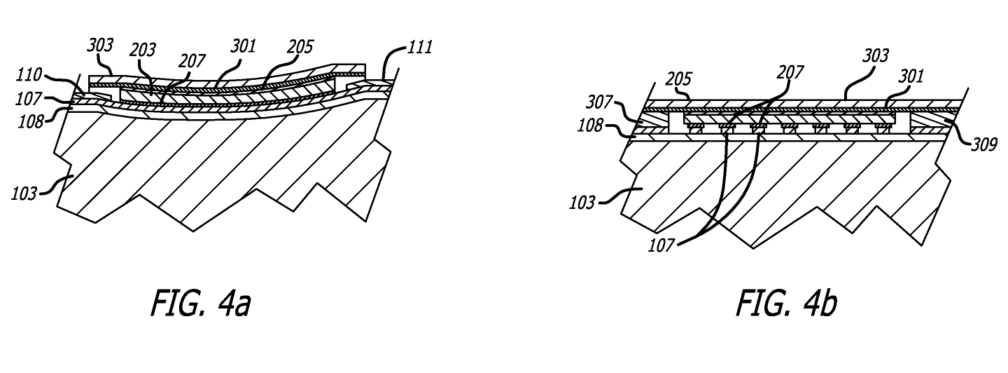

FIGS. 4a and 4b illustrate an assembled curved ultrasonic array transducer made from the process illustrated in FIGS. 1(a), 1(b), 2(a), 2(b), 3(a), and 3(b).

The components, steps, features, objects, benefits and advantages that have been discussed are merely illustrative. None of them, nor the discussions relating to them, are intended to limit the scope of protection in any way. Numerous other embodiments are also contemplated. These include embodiments that have fewer, additional, and/or different components, steps, features, objects, benefits and advantages. These also include embodiments in which the components and/or steps are arranged and/or ordered differently.

For example, one or more additional acoustic matching layers may be added on the top surface of the matching later 305. It may be bonded, coated, or deposited by any means. The matching layer may be configured to match the piezoelectric material to the load medium such as to water, saline, human tissue, or other biological or non-biological material.

As illustrated in FIGS. 1a-4b, the ultrasonic array transducer may not contain any type of acoustic lens, and/or may not require any wire bonds to the element electrodes 207.

In still other configurations, there may be no matching layers; no element electrode 207 on the piezoelectric material 203; the separate common electrodes 205 and 301 may be replaced by a deposited electrode which creates a common connection between the piezoelectric material 203 and the common electrodes 113 and/or 115 on the flexible circuit; The curvature in the off-image axis (elevation) may be concave or convex; the curvature in the on-image axis (azimuth) may be concave or convex; and/or the piezoelectric material may be deposited or formed directly on the curved electroplated substrate by sputtering, dip-coating, or spin-coating.

An adhesive may be used as one form of bonding. When two components are bonded together with an adhesive, spaces that remain after the bonding may be filled with the adhesive.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

All articles, patents, patent applications, and other publications which have been cited in this disclosure are hereby incorporated herein by reference.

The phrase “means for” when used in a claim is intended to and should be interpreted to embrace the corresponding structures and materials that have been described and their equivalents. Similarly, the phrase “step for” when used in a claim embraces the corresponding acts that have been described and their equivalents. The absence of these phrases means that the claim is not intended to and should not be interpreted to be limited to any of the corresponding structures, materials, or acts or to their equivalents.

Nothing that has been stated or illustrated is intended or should be interpreted to cause a dedication of any component, step, feature, object, benefit, advantage, or equivalent to the public, regardless of whether it is recited in the claims.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents.

1. A method of manufacturing an ultrasonic array transducer having an array of piezoelectric elements with a curvature that enables the piezoelectric elements to control the way in which ultrasonic energy is focused by the transducer, the method comprising:
creating a substrate that has a set of element electrodes on a surface of the substrate, each electrically isolated from the others and configured to correspond to the location of one of the piezoelectric elements; and
bonding a piezoelectric component which includes piezoelectric material to the surface of the substrate such that each element electrode is juxtaposed next to the piezoelectric component,
wherein the surface of the substrate and/or the piezoelectric material has/have the curvature while they are separated and prior to the bonding, and
wherein the bonding is performed in a manner that results in the array of piezoelectric elements having the curvature.

2. The method of manufacturing of claim 1 wherein:
the piezoelectric component includes a set of element electrodes on one side of the piezoelectric material, each electrically isolated from the others and configured to correspond to the location of one of the piezoelectric elements, and
the element electrodes on the substrate are oriented with respect to the element electrodes on the piezoelectric material prior to the bonding such that the element electrodes on the piezoelectric material come in electrical contact with the element electrodes on the substrate when bonded.

3. The method of manufacturing of claim 1 wherein:
the element electrodes on the substrate rest against a side of the piezoelectric material after the bonding, and
there is no additional set of element electrodes between the element electrodes on the substrate and the piezoelectric material either before, during, or after the bonding.

4. The method of manufacturing of claim 1 wherein creating the substrate includes creating the curvature in a surface of backing material.

5. The method of manufacturing of claim 4 wherein creating the substrate includes bonding the set of element electrodes to the curvature in the surface of the backing material.

6. The method of manufacturing of claim 5 wherein the element electrodes are part of a substantially flat, flexible circuit interconnect which includes a flexible support member and wherein the flexible circuit interconnect is bonded to the curvature in the surface of the backing.

7. The method of manufacturing of claim 5 wherein the curvature is imparted to the flexible circuit interconnect in a permanent fashion before it is bonded to the curvature in the surface of the backing.

8. The method of manufacturing of claim 5 wherein the curvature is not imparted to the flexible circuit interconnect in a permanent fashion before it is bonded to the surface of the curvature in the backing.

9. The method of manufacturing of claim 1 wherein the piezoelectric material has the curvature while separated from and before being bonded to the surface of the substrate.

10. The method of manufacturing of claim 9 wherein only a portion of the piezoelectric material has the curvature while separated from and before being bonded to the substrate.

11. The method of claim 10 wherein only a portion of the piezoelectric material has the curvature after being bonded to the substrate.

12. The method of manufacturing of claim 1 wherein the piezoelectric material and the substrate have the curvature while separated from and before being bonded to each other.

13. The method of manufacturing of claim 1 wherein the piezoelectric material does not have the curvature while separated from and before being bonded to the substrate.

14. The method of manufacturing of claim 1 wherein the element electrodes are juxtaposed next to a side of the piezoelectric component and further comprising creating at least one common electrode on an opposite side of the piezoelectric material.

15. The method of manufacturing of claim 1 wherein the curvature is in only a single plane.

16. The method of manufacturing of claim 1 wherein the curvature is in multiple planes.

17. A substrate configured to be bonded to a piezoelectric component so as to create an ultrasonic array transducer having an array of piezoelectric elements with a curvature that enables the piezoelectric elements to control the way in which ultrasonic energy is focused by the transducer, the substrate comprising:
the curvature in a surface of the substrate while it is separated from the piezoelectric component; and
a set of element electrodes on the surface of the substrate, each electrically isolated from the others and configured to correspond to the location of one of the piezoelectric elements.

18. The substrate of claim 14 further comprising a flexible support member between the curvature in the surface of the substrate and the set of element electrodes.

19. A piezoelectric component configured to be bonded to a substrate so as to create an ultrasonic array transducer having an array of piezoelectric elements with a curvature that enables the piezoelectric elements to control the way in which ultrasonic energy is focused by the transducer, the piezoelectric component comprising:
piezoelectric material; and
a set of element electrodes on a surface of the piezoelectric material, each electrically isolated from the others and configured to correspond to the location of one of the piezoelectric elements,
wherein the piezoelectric material and the element electrodes have the curvature before being bonded to the substrate.

20. The piezoelectric component of claim 19 further comprising at least one common electrode on an opposite side of the piezoelectric material which also has the curvature before being bonded to the substrate.

21. The piezoelectric component of claim 20 wherein the curvature is in only a single plane.

22. The piezoelectric component of claim 20 wherein the curvature is in multiple planes.
